(19) United States
(12) Patent Application Publication
(10) Pub. No.: US 2025/0070682 A1
(43) Pub. Date: Feb. 27, 2025

(54) POWER CONVERSION DEVICE

(71) Applicant: Mitsubishi Electric Corporation, Tokyo (JP)

(72) Inventors: Kota HOZUMI, Tokyo (JP); Takuya NAKAMURA, Tokyo (JP)

(73) Assignee: Mitsubishi Electric Corporation, Tokyo (JP)

(21) Appl. No.: 18/725,542

(22) PCT Filed: Oct. 31, 2022
(86) PCT No.: PCT/JP2022/040689

§ 371 Date: Jun. 28, 2024

(30) Foreign Application Priority Data
Feb. 25, 2022 (JP) 2022-027408

(51) Int. Cl. H02M 7/00; H05K 7/20

(52) U.S. Cl. CPC H02M 7/003; H05K 7/209

(57) ABSTRACT

Heat of a heat-generating busbar is dissipated to a cooler via a heat spreader. A space between the heat spreader and the busbar is filled with a heat dissipation compound, and a labyrinth structure is formed around the outer periphery of a part for which dust-proofing is needed, thus providing dust-proofing. In the labyrinth structure, a first rib of the cooler is provided so as to surround the part and a second rib of a resin mold covering the part is also formed so as to surround the part. Further, a first rib discontinuous section which is a partially discontinuous section with no rib is provided to the first rib, and the heat spreader and a filler are provided at the first rib discontinuous section, to achieve cooling and dust-proofing.

### TECHNICAL FIELD

The present disclosure relates to a power conversion device.

### BACKGROUND ART

Electrified vehicles, i.e., a hybrid car (HV: Hybrid Vehicle), a plug-in hybrid car (PHV: Plug-in Hybrid Vehicle, PHEV: Plug-in Hybrid Electrical Vehicle, registered trademark), an electric car (EV: Electric Vehicle, registered trademark), and a fuel cell car (FCV: Fuel Cell Vehicle), are provided with power conversion devices such as an inverter for driving a drive motor and a converter for boosting battery power supply voltage, which are components for electrification.

In recent years, such power conversion devices have been required to be reduced in cost. In addition, in vehicles such as HV, PHV, and PHEV, since components for electrification are provided as well as an engine, small-sized components have been particularly required.

In addition, among components of the same size, a component having an improved power density is more required. In order to improve a power density, a heat generating part is brought into contact with a cooler over as large an area as possible, so that the heat generating part is efficiently cooled, whereby the power density can be improved. However, increasing a heat dissipation area makes it difficult to reduce the sizes of components.

In many cases, a motor and power conversion devices provided to an electrified vehicle are manufactured by each manufacturing supplier and are integrated in assembling in a vehicle structure at a client.

For such power conversion devices, dust-proofness is required during a period from manufacturing to integration, e.g., in transportation.

Also after a vehicle is assembled, dust-proofness is required against high-pressure washing, oil mist, contamination, and the like.

In general, as a structure for imparting dust-proofness, a method of providing a labyrinth structure to ensure dust-proofness is known (see, for example, Patent Document 1).

### CITATION LIST

### Patent Document

Patent Document 1: Japanese Patent No. 3216964 (pages 2-3, FIG. 4)

### SUMMARY OF THE INVENTION

### Problem to be Solved by the Invention

However, in a case of providing a labyrinth structure as shown in Patent Document 1, a space for one function of dust-proofing is needed, which makes it difficult to reduce the sizes of components.

As a structure for imparting dust-proofness, other than the labyrinth structure, a water-proof and dust-proof packing or a liquid seal material is generally used to ensure dust-proofness.

However, in this case, since a member is added, it is difficult to reduce the cost, and as in the case of the labyrinth structure, a space is needed, so that there is difficulty in size reduction.

The present disclosure has been made to solve the above problem, and an object of the present disclosure is to provide a power conversion device that allows size reduction and improves heat dissipation of a heat generating part while ensuring dust-proofness.

### Means to Solve the Problem

A power conversion device according to the present disclosure includes: a first part which generates heat; a second part for which dust-proofing is needed; a cooler which cools the first part; and a heat dissipation member which is provided between the first part and the cooler, and which dissipates the heat generated by the first part, to the cooler, wherein the cooler has a first rib portion forming a labyrinth structure around an outer periphery of the second part, a cutout portion is provided to the first rib portion, and the heat dissipation member is placed at the cutout portion.

### Effect of the Invention

The power conversion device according to the present disclosure allows size reduction and improves heat dissipation of a heat generating part while ensuring dust-proofness.

### BRIEF DESCRIPTION OF THE DRAWINGS

FIG. 1 is a perspective view showing a power conversion device according to embodiment 1.

FIG. 2 is a top view showing the power conversion device according to embodiment 1.

FIG. 3 is a horizontal-direction sectional view showing the power conversion device according to embodiment 1.

FIG. 4 is a vertical-direction sectional view showing the power conversion device according to embodiment 1.

FIG. 5 is an exploded perspective view showing the power conversion device according to embodiment 1.

FIG. 6 is an exploded perspective view showing a power conversion device according to embodiment 2.

FIG. 7 is an exploded perspective view showing a power conversion device according to embodiment 3.

FIG. 8 is an exploded perspective view showing a power conversion device according to embodiment 4.

FIG. 9 is a top view showing the power conversion device according to embodiment 4.

FIG. 10 is a front view showing the power conversion device according to embodiment 4.

FIG. 11 is a sectional view showing the power conversion device according to embodiment 4.

### DESCRIPTION OF EMBODIMENTS

### Embodiment 1

Hereinafter, embodiment 1 will be described with reference to the drawings.

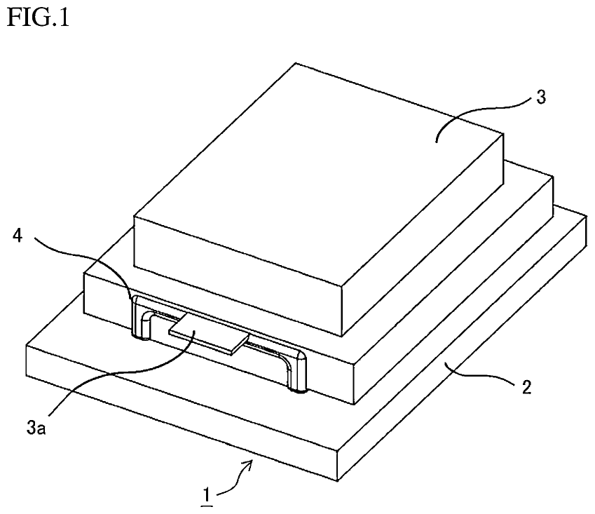

FIG. 1 is a perspective view showing a power conversion device according to embodiment 1.

In FIG. 1, a power conversion device 1 includes a busbar 3a (first part) which transfers power from a power converter such as an inverter, and a cooler 2 for cooling the busbar 3a. The busbar 3a is made of copper and generates heat when transferring power.

The busbar 3a is formed with a resin mold 3 (structure member) through insert molding or the like. A heat dissipation compound 4 (filler) fills a space between a heat spreader described later and the busbar 3a. The filler may be provided by being applied. The busbar 3a is brought into contact with the cooler 2 via the heat dissipation compound 4, so that heat of the busbar 3a is transferred to cooling water in the cooler 2, thus suppressing overheating of the busbar 3a.

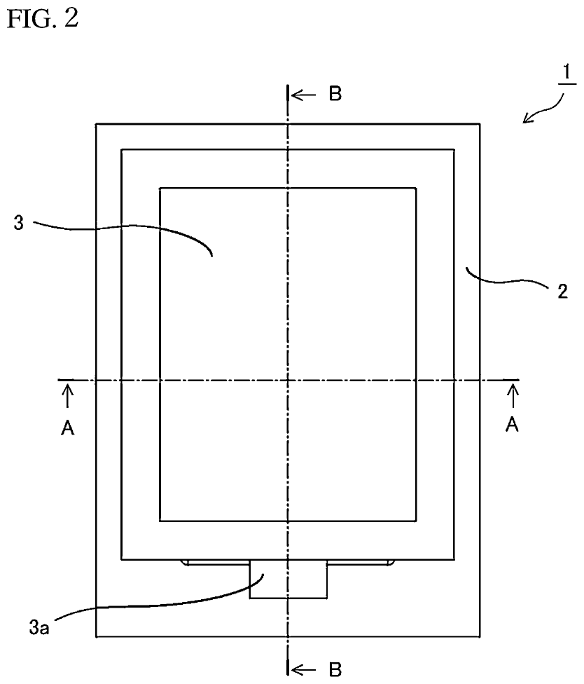

FIG. 2 is a top view showing the power conversion device according to embodiment 1.

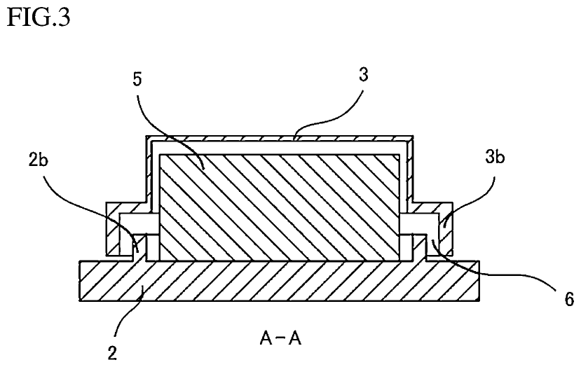

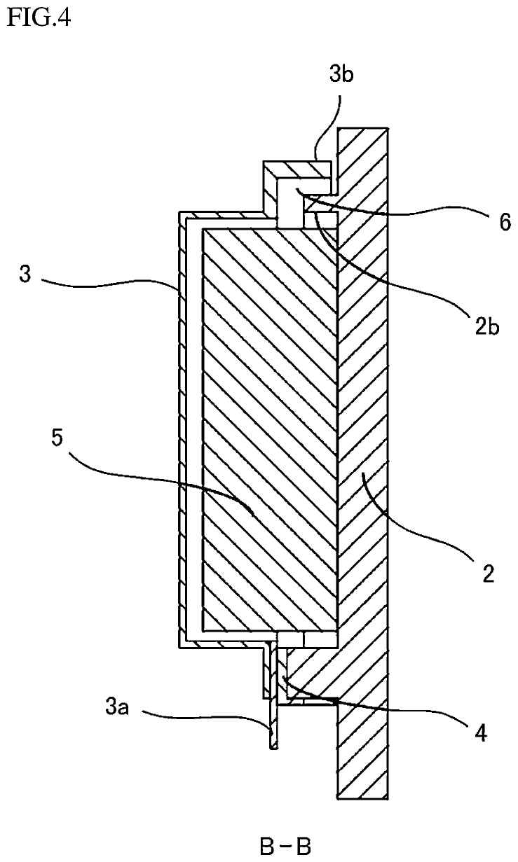

In FIG. 2, reference characters 1 to 3 and 3a are the same as those in FIG. 1. An A-A cross-section of FIG. 2 is shown in FIG. 3, and a B-B cross-section is shown in FIG. 4.

FIG. 3 is a horizontal-direction sectional view showing the power conversion device according to embodiment 1.

FIG. 3 shows an A-A cross-section of FIG. 2.

In FIG. 3, reference characters 2 and 3 are the same as those in FIG. 1. In FIG. 3, a part 5 (second part) such as a power converter in which an inverter formed of a power semiconductor, and the like, are stored is a part for which dust-proofing is needed as well as cooling, and is directly or indirectly attached to the cooler 2. A first rib 2b (first rib portion) is provided so as to surround the part 5 for which dust-proofing is needed. For dust-proofing, a labyrinth structure 6 is formed by the first rib 2b and a second rib described later. The bottom of the first rib 2b and the cooler 2 are contiguous to each other, so that the first rib 2b is a part of the cooler 2.

A second rib 3b (second rib portion) is integrated with the resin mold 3, and similarly to the first rib 2b, is provided so as to surround the part 5 for which dust-proofing is needed, thus forming the labyrinth structure 6.

FIG. 4 is a vertical-direction sectional view showing the power conversion device according to embodiment 1.

FIG. 4 shows a B-B cross-section of FIG. 2.

In FIG. 4, reference characters 2, 3, 3a, and 4 are the same as those in FIG. 1, and reference characters 2b, 3b, 5, and 6 are the same as those in FIG. 3.

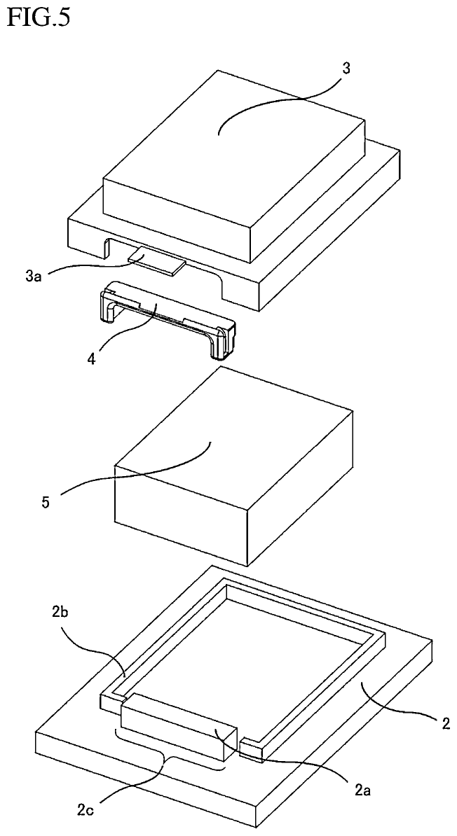

FIG. 5 is an exploded perspective view showing the power conversion device according to embodiment 1.

In FIG. 5, reference characters 2, 2b, 3, 3a, 4, and 5 are the same as those in FIG. 4. In FIG. 5, the heat spreader 2a (heat dissipation member) is for transferring heat of the busbar 3a extending from the part 5, to the cooler 2.

The first rib 2b provided so as to surround the part 5 for which dust-proofing is needed has, partially, a first rib discontinuous section 2c (cutout portion) which is a discontinuous section with no rib.

The heat spreader 2a is provided at the first rib discontinuous section 2c, in order to cool the busbar 3a. The bottom of the heat spreader 2a and the cooler 2 are contiguous to each other, so that the heat spreader 2a is a part of the cooler 2.

The busbar 3a is placed vertically upward of the heat spreader 2a, and a space between the heat spreader 2a and the busbar 3a is filled with the heat dissipation compound 4. Although not shown, a space between the first rib 2b and the heat spreader 2a is also filled with the heat dissipation compound 4.

Next, operation will be described.

Embodiment 1 relates to the labyrinth structure 6 for dust-proofing for the part 5 for which dust-proofing is needed and a structure for cooling the busbar 3a which is a heat generating part, in the power conversion device 1.

In the structure of the power conversion device 1 of embodiment 1, on the cooler 2 for cooling the busbar 3a, the heat spreader 2a for transferring heat of the busbar 3a to the cooler 2, the heat dissipation compound 4, and the part 5 for which dust-proofing is needed, are provided, and further, the first rib 2b forming the labyrinth structure 6 is provided.

The first rib 2b has the first rib discontinuous section 2c which is a partially discontinuous section with no rib, and the heat spreader 2a which dissipates heat generated by the busbar 3a for the purpose of cooling is provided at the first rib discontinuous section 2c.

The busbar 3a which generates heat is placed vertically upward of the heat spreader 2a, and a space between the heat spreader 2a and the busbar 3a is filled with the heat dissipation compound 4. In addition, a space between the first rib 2b and the heat spreader 2a is also filled with the heat dissipation compound 4.

The busbar 3a which is the heat generating part of the power conversion device 1 is brought into contact with the cooler 2 via a heat dissipation portion which is the heat spreader 2a and the heat dissipation compound 4, and heat of the busbar 3a is transferred to the cooling water in the cooler 2, whereby overheating of the busbar 3a is suppressed.

In addition, a space between the heat spreader 2a and the busbar 3a is filled with the heat dissipation compound 4 without any gap, to dissipate heat of the busbar 3a.

In embodiment 1, the busbar 3a has an increased contact surface with the cooler 2 by interposing the heat dissipation portion formed by the heat spreader 2a and the heat dissipation compound 4.

On the other hand, regarding dust-proofing for the part 5, the labyrinth structure 6 is formed around the outer periphery of the part 5, thus ensuring dust-proofing.

Therefore, the first rib 2b is provided so as to surround the part 5 for which dust-proofing is needed and which is directly or indirectly attached to the cooler 2.

The resin mold 3 molded with the busbar 3a by insert molding or the like is formed integrally with the second rib 3b, and the second rib 3b is provided so as to surround the part 5 for which dust-proofing is needed, as with the first rib 2b, thus forming the labyrinth structure 6 in combination with the first rib 2b.

In addition, the first rib 2b and the second rib 3b forming the labyrinth structure 6 are partially cut out, the busbar 3a is placed at the cut-out section, and dust-proofness is obtained with the heat dissipation compound 4 filling the space between the heat spreader 2a and the busbar 3a.

With this structure, dust-proofing for the part 5 is ensured.

In the power conversion device for an electrified vehicle, in general, a part is attached to the cooler 2 provided with a cooling water path. In this case, the contact surface with the cooler is a surface via which a heat generating part can be cooled, and by increasing the contact area between the heat generating part and the cooler, heat generation in the heat generating part can be suppressed.

In embodiment 1, the contact area with the cooler is increased over the part 5 which is a heat generating part and the busbar 3a which transfers heat thereof, and a function needed for dust-proofness is ensured, thus achieving component size reduction and cost reduction.

That is, dust-proofness is imparted by the heat dissipation compound 4 and an area needed for ensuring dust-proofness is reduced, while the cooling area for the busbar 3a is increased accordingly. Thus, for example, in the power conversion device having the same size, larger current can flow, and as a result, component size reduction is achieved.

A power conversion device provided in an electrified vehicle, in particular, an inverter is often required to be increased in output as well as size reduction and cost reduction, so that current flowing through the busbar 3a is likely to increase.

For dissipating heat of the busbar 3a, it is necessary to increase the area of the heat dissipation portion including the heat spreader 2a, so that a space for dissipating heat of the busbar 3a is needed. Therefore, the labyrinth structure 6 is removed in an area around the busbar 3a, and in exchange, dust-proofness is ensured by the heat spreader 2a and the heat dissipation compound 4 which perform heat dissipation.

As described above, according to embodiment 1, by increasing the contact area between the busbar 3a which is a heat generating part and the cooler, the heat generating part can be efficiently cooled.

The labyrinth structure 6 around the busbar 3a is replaced with a dust-proof structure by the heat spreader 2a and the heat dissipation compound 4, whereby the size of the power conversion device can be reduced.

In addition, by imparting dust-proofness by the labyrinth structure 6, it becomes unnecessary to provide an additional member such as a packing for dust-proofing, and dust-proofness is ensured until assembling, resulting in cost reduction.

### Embodiment 2

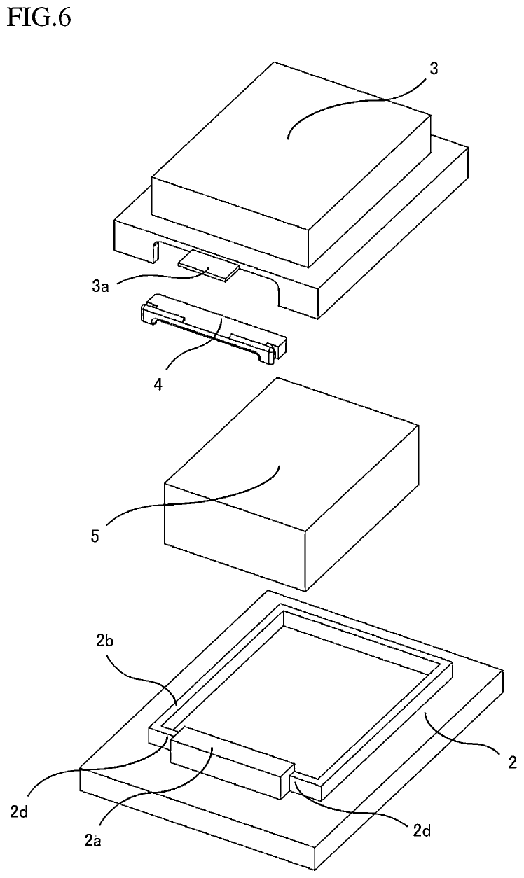

FIG. 6 is an exploded perspective view showing a power conversion device according to embodiment 2.

In FIG. 6, reference characters 2, 2a, 2b, 3, 3a, 4, and 5 are the same as those in FIG. 5 and the description thereof is omitted. In FIG. 6, a connection section 2d between the first rib 2b and the heat spreader 2a is shown.

In embodiment 2, as compared to the power conversion device 1 of embodiment 1, the first rib 2b extends to the heat spreader 2a so that there is no gap between the first rib 2b and the heat spreader 2a.

In embodiment 1, since there are gaps between the heat spreader 2a and the first rib 2b, the heat dissipation compound 4 needs to fill also these gaps. However, with the structure of embodiment 2, the filling amount of the heat dissipation compound 4 can be decreased.

As described above, according to embodiment 2, the effect of embodiment 1 that the heat generating part can be efficiently cooled by increasing the contact area between the busbar 3a which is a heat generating part and the cooler, is provided, and in addition, the filling amount of the heat dissipation compound 4 can be decreased.

### Embodiment 3

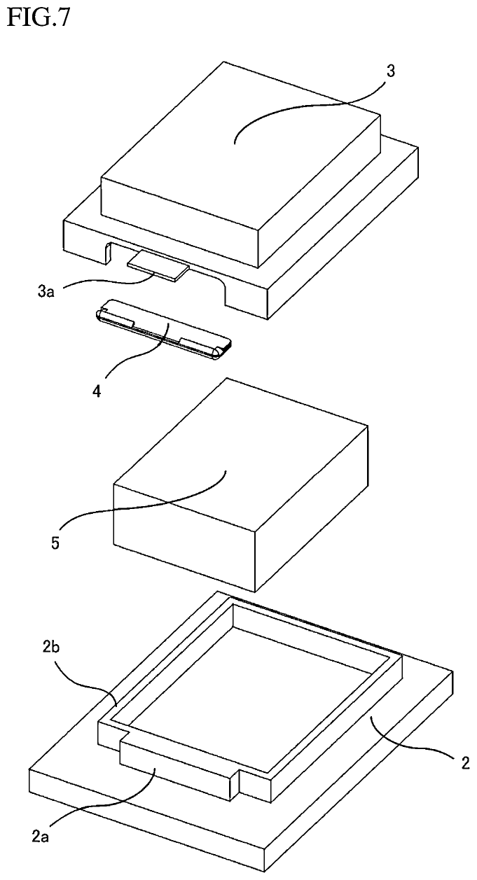

FIG. 7 is an exploded perspective view showing a power conversion device according to embodiment 3.

In FIG. 7, reference characters 2, 2a, 2b, 3, 3a, 4, and 5 are the same as those in FIG. 5 and the description thereof is omitted. In FIG. 7, the heights in the vertically upward direction of the first rib 2b and the heat spreader 2a are the same.

In embodiment 3, as compared to the power conversion device 1 of embodiment 2, the heights in the vertically upward direction of the first rib 2b and the heat spreader 2a are set to be the same.

With this structure, the filling direction of the heat dissipation compound 4 can become only a plane direction, so that workability in applying the heat dissipation compound 4 can be improved.

As described above, according to embodiment 3, the effect of embodiment 1 that the heat generating part can be efficiently cooled by increasing the contact area between the busbar 3a which is a heat generating part and the cooler, is provided, and in addition, filling of the heat dissipation compound 4 is needed only in a plane direction and thus workability in applying the heat dissipation compound 4 can be improved.

### Embodiment 4

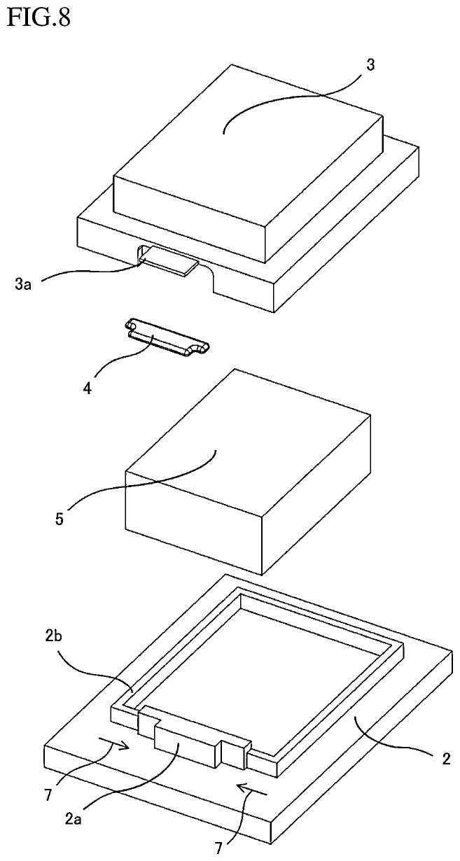

FIG. 8 is an exploded perspective view showing a power conversion device according to embodiment 4.

In FIG. 8, reference characters 2, 2a, 2b, 3, 3a, 4, and 5 are the same as those in FIG. 5 and the description thereof is omitted. In FIG. 8, the shape of the heat spreader 2a is changed. The second rib 3b is extended in the directions of arrows 7 until overlapping parts of the heat spreader 2a. The arrows 7 represent the directions in which the second rib 3b overlaps the heat spreader 2a.

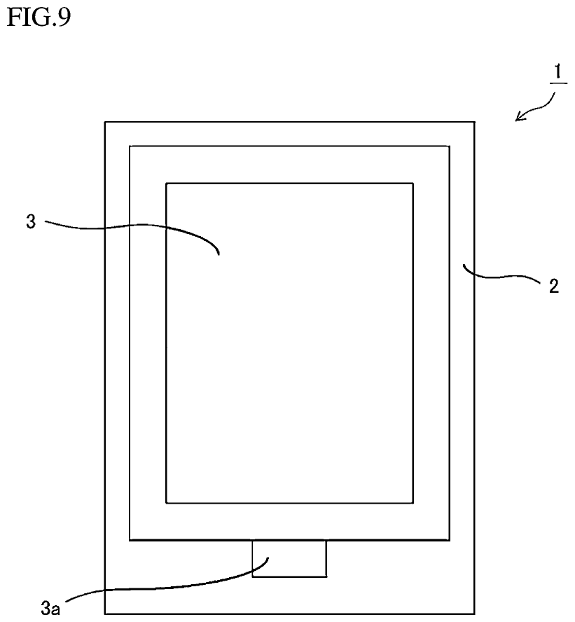

FIG. 9 is a top view showing the power conversion device according to embodiment 4.

In FIG. 9 showing the top view of the power conversion device 1, reference characters 2, 3, and 3a are the same as those in FIG. 8.

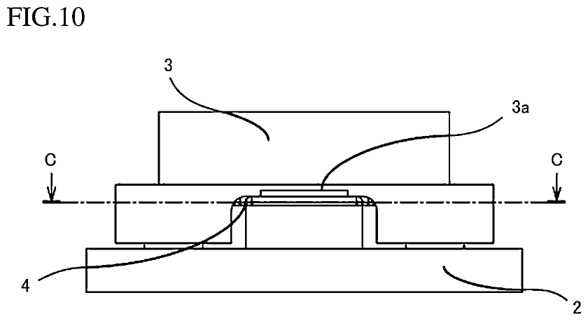

FIG. 10 is a front view showing the power conversion device according to embodiment 4.

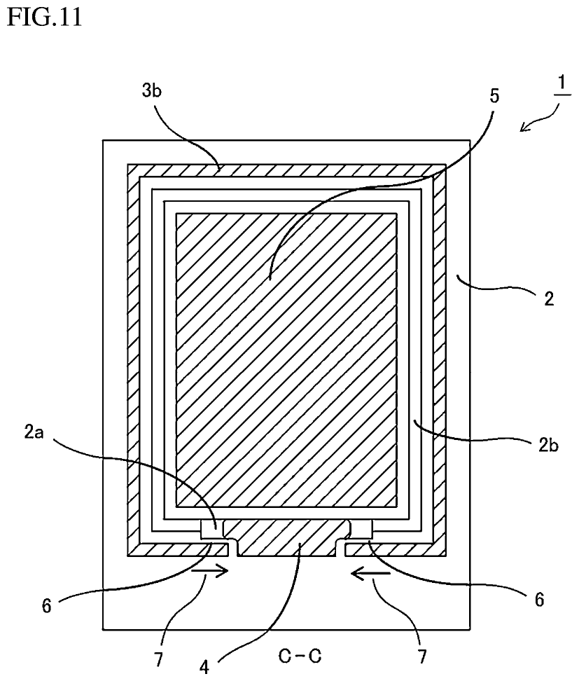

In FIG. 10, reference characters 2, 3, 3a, and 4 are the same as those in FIG. 8. A C-C cross-section of FIG. 10 is shown in FIG. 11.

In FIG. 11, reference characters 2, 2a, 2b, 4, 5, and 7 are the same as those in FIG. 8. In FIG. 11, the second rib 3b extends in the directions of arrows 7 and forms parts overlapping the heat spreader 2a. The parts overlapping the heat spreader 2a form the labyrinth structure 6.

In embodiment 4, as compared to the power conversion device 1 of embodiment 2, the second rib 3b extends in the overlapping directions shown by the arrows 7 until overlapping parts of the heat spreader 2a of the cooler 2, and the parts overlapping the heat spreader 2a form the labyrinth structure 6.

With this structure, the rib heights of the first rib 2b and the second rib 3b need not be aligned, and as in embodiment 3, filling of the heat dissipation compound 4 is needed only in the plane direction on the heat spreader 2a, while dust-proofness can be ensured for the part 5 for which dust-proofing is needed.

For example, it is assumed that the cooler 2 is formed by die casting of aluminum and the thickness of the rib is small. In this case, if the height of the rib is too high, it is difficult for aluminum to reach the top of the rib during die casting, resulting in increase of a defect rate. Therefore, it is necessary to determine the height of the rib in such a range that the defect rate does not increase.

In a case where the height of the heat spreader 2a is lowered to the height of the rib, the busbar 3a made of copper and placed vertically upward of the heat spreader 2a needs to be close to the heat spreader 2a, so that the length of the busbar 3a made of copper increases and the cost increases accordingly.

In the structure in embodiment 4, the heights of the ribs need not be aligned, and therefore, even in a case where the cooler 2 is formed by die casting of aluminum, increase in the cost due to increase in the length of the busbar 3a made of copper does not occur.

As described above, according to embodiment 4, the effect of embodiment 1 that the heat generating part can be efficiently cooled by increasing the contact area between the busbar 3a which is a heat generating part and the cooler, is provided, and in addition, an effect similar to that of embodiment 3 can be obtained without aligning the heights of the first rib 2b and the busbar 3a.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure. It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 power conversion device
2 cooler
2a heat spreader
2b first rib
2c first rib discontinuous section
2d connection section
3 resin mold
3a busbar
3b second rib
4 heat dissipation compound
5 part
6 labyrinth structure
7 arrow

1. A power conversion device comprising:
a first part which generates heat;
a second part for which dust-proofing is needed;
a cooler which cools the first part; and
a heat dissipation member which is provided between the first part and the cooler, and which dissipates the heat generated by the first part, to the cooler, wherein
the cooler has a first rib portion forming a labyrinth structure around an outer periphery of the second part,
a cutout portion is provided to the first rib portion, and
the heat dissipation member is placed at the cutout portion.

2. The power conversion device according to claim 1, further comprising a structure member covering the second part, wherein
the structure member has a second rib portion forming the labyrinth structure, together with the first rib portion.

3. The power conversion device according to claim 2, wherein
the second rib portion forms the labyrinth structure, together with a part of the heat dissipation member.

4. The power conversion device according to claim 1, wherein
a space between the first part and the heat dissipation member is filled with a heat-dissipating filler.

5. The power conversion device according to claim 4, wherein
at the cutout portion of the first rib portion, the space between the first rib portion and the heat dissipation member is filled with the filler.

6. The power conversion device according to claim 1, wherein
at the cutout portion of the first rib portion, the first rib portion and the heat dissipation member are connected without any gap.

7. The power conversion device according to claim 6, wherein
the heat dissipation member is formed such that a length thereof in a direction vertical to a contact surface with the cooler is the same as a length in the vertical direction of the first rib portion.

8. A power conversion device comprising:
a busbar connected to a power converter and extending outward from the power converter;
a cooler which is provided under the power converter and cools the power converter;
a first rib provided at the cooler and for forming a labyrinth structure for providing dust-proofing for the power converter, and a second rib formed at a resin mold covering the power converter from above;
a heat spreader for dissipating heat of the busbar, the heat spreader being formed at a cutout portion where the first rib is cut out around the busbar; and
a filler filling a space between the heat spreader and the busbar, wherein
both of heat dissipation for the busbar and dust-proofing for the power converter are realized by the heat spreader and the filler.

9. The power conversion device according to claim 2, wherein
a space between the first part and the heat dissipation member is filled with a heat-dissipating filler.

10. The power conversion device according to claim 3, wherein
a space between the first part and the heat dissipation member is filled with a heat-dissipating filler.

11. The power conversion device according to claim 9, wherein
at the cutout portion of the first rib portion, the space between the first rib portion and the heat dissipation member is filled with the filler.

12. The power conversion device according to claim 10, wherein
at the cutout portion of the first rib portion, the space between the first rib portion and the heat dissipation member is filled with the filler.

13. The power conversion device according to claim 2, wherein
at the cutout portion of the first rib portion, the first rib portion and the heat dissipation member are connected without any gap.

14. The power conversion device according to claim 3, wherein
at the cutout portion of the first rib portion, the first rib portion and the heat dissipation member are connected without any gap.

15. The power conversion device according to claim 4, wherein
at the cutout portion of the first rib portion, the first rib portion and the heat dissipation member are connected without any gap.

16. The power conversion device according to claim 9, wherein
at the cutout portion of the first rib portion, the first rib portion and the heat dissipation member are connected without any gap.

17. The power conversion device according to claim 10, wherein
at the cutout portion of the first rib portion, the first rib portion and the heat dissipation member are connected without any gap.

18. The power conversion device according to claim 13, wherein
the heat dissipation member is formed such that a length thereof in a direction vertical to a contact surface with the cooler is the same as a length in the vertical direction of the first rib portion.

19. The power conversion device according to claim 14, wherein
the heat dissipation member is formed such that a length thereof in a direction vertical to a contact surface with the cooler is the same as a length in the vertical direction of the first rib portion.

20. The power conversion device according to claim 15, wherein
the heat dissipation member is formed such that a length thereof in a direction vertical to a contact surface with the cooler is the same as a length in the vertical direction of the first rib portion.
